(19) United States
(12) Patent Application Publication
(10) Pub. No.: US 2023/0406692 A1
(43) Pub. Date: Dec. 21, 2023

(54) MICROELECTROMECHANICAL SYSTEM (MEMS) MICROPHONE AND FABRICATION METHOD THEREOF

(71) Applicant: UNITED MICROELECTRONICS CORP., Hsin-Chu City (TW)

(72) Inventors: Jung-Hao Chang, Taoyuan City (TW); Weng-Yi Chen, Hsinchu County (TW)

(73) Assignee: UNITED MICROELECTRONICS CORP., Hsin-Chu City (TW)

(21) Appl. No.: 17/878,924

(22) Filed: Aug. 2, 2022

(30) Foreign Application Priority Data
Jun. 21, 2022 (TW) 111123061

(51) Int. Cl. B81B 3/00; B81C 1/00

(52) U.S. Cl. CPC B81B 3/0021; B81C 1/00158; B81B 2201/0257; B81B 2203/0127; B81B 2203/0315; B81C 2201/0132; B81C 2201/0156; B81C 2201/0176

(57) ABSTRACT

A microelectromechanical system (MEMS) microphone includes a substrate, a membrane supported relative to the substrate, an opening extending through the entire thickness of the membrane, and a spacer disposed on the sidewall of the opening. The spacer protrudes beyond the top surface of the membrane.

### BACKGROUND OF THE INVENTION

### 1. Field of the Invention

The invention relates to a micro-electromechanical system (MEMS) element and a manufacturing method thereof, in particular to a MEMS microphone and a manufacturing method thereof.

### 2. Description of the Prior Art

MEMS microphones have been widely used, and their main principle of operation is to use a small and flexible diaphragm or membrane that can respond to changes in sound waves. The film generally has electrically conductive properties or comprises an electrode and a variable capacitance is formed by a backplane conductor having a via and a film to detect micro-bending of the film. The capacitance values generated by the film and the backplane conductor are measured and become the output signal of the microphone.

In MEMS microphone products, the signal-to-noise ratio (SNR) and low-frequency roll-off (LFRO) are important indicators. Microphones with higher SNR can be used in smartphones, while microphones with flatter LFRO are suitable for noise reduction products. The microphones for higher-end products need to satisfy both conditions. However, there are still many problems to be overcome in the current MEMS process to meet the aforementioned two requirements at the same time.

### SUMMARY OF THE INVENTION

It is one object of the present invention to provide an improved MEMS microphone and its manufacturing method to solve the deficiencies or shortcomings of the prior art.

One aspect of the invention provides a microelectromechanical system (MEMS) microphone including a substrate; a membrane supported relative to the substrate, wherein the membrane comprises an inner portion and an outer portion; a first spacer disposed on a sidewall of the inner portion directly facing the outer portion; a second spacer disposed on a sidewall of the outer portion directly facing the inner portion; and a slit between the first spacer and the second spacer.

According to some embodiments, the substrate is a silicon substrate and the membrane is a polysilicon membrane.

According to some embodiments, the MEMS microphone further includes a cavity in the substrate and under the membrane; a backplate above the membrane, wherein the membrane comprises a top surface facing the backplate; and an air gap between the membrane and the backplate.

According to some embodiments, the slit communicates the air gap with the cavity.

According to some embodiments, the first spacer and the second spacer protrude from the top surface of the membrane.

According to some embodiments, a top surface of the first spacer and the second spacer is flush with the top surface of the membrane.

According to some embodiments, a top surface of the first spacer and the second spacer is lower than the top surface of the membrane.

According to some embodiments, the first spacer comprises silicon nitride, silicon carbide, silicon oxycarbide, silicon, polysilicon, titanium nitride, or any combinations thereof.

According to some embodiments, the second spacer comprises silicon nitride, silicon carbide, silicon oxycarbide, silicon, polysilicon, titanium nitride, or any combinations thereof.

According to some embodiments, the MEMS microphone further includes a silicon oxide layer between the outer portion and the substrate.

Another aspect of the invention provides a method of fabricating a MEMS microphone. A substrate is provided. A membrane supported relative to the substrate is formed. The membrane comprises an inner portion and an outer portion. A first spacer is formed on a sidewall of the inner portion directly facing the outer portion. A second spacer is formed on a sidewall of the outer portion directly facing the inner portion. A slit is formed between the first spacer and the second spacer.

According to some embodiments, the substrate is a silicon substrate and the membrane is a polysilicon membrane.

According to some embodiments, the method further includes the steps of: forming a cavity in the substrate and under the membrane; forming a backplate above the membrane; and forming an air gap between the membrane and the backplate.

According to some embodiments, the slit communicates the air gap with the cavity.

According to some embodiments, the first spacer comprises silicon nitride, silicon carbide, silicon oxycarbide, silicon, polysilicon, titanium nitride, or any combinations thereof.

According to some embodiments, the second spacer comprises silicon nitride, silicon carbide, silicon oxycarbide, silicon, polysilicon, titanium nitride, or any combinations thereof.

According to some embodiments, the method further includes the step of forming a silicon oxide layer between the outer portion and the substrate.

Another aspect of the invention provides a MEMS microphone including a substrate; a membrane supported relative to the substrate; an opening penetrating through an entire thickness of the membrane; and a spacer disposed on a sidewall of the opening.

Still another aspect of the invention provides a method of fabricating a MEMS microphone including the steps of: providing a substrate; forming a membrane supported relative to the substrate; forming an opening penetrating through an entire thickness of the membrane; and forming a spacer disposed on a sidewall of the opening.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic cross-sectional view of a MEMS microphone according to an embodiment of the present invention.

FIG. 2 is a top view and an enlarged view of the membrane of the MEMS microphone.

FIG. 3 is a schematic cross-sectional view of the membrane in the enlarged area of FIG. 2 taken along line I-I′.

FIG. 4 to FIG. 9 are schematic diagrams illustrating a method of fabricating a membrane of a MEMS microphone according to an embodiment of the present invention.

FIG. 10 and FIG. 11 are schematic cross-sectional views of membranes according to some embodiments of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

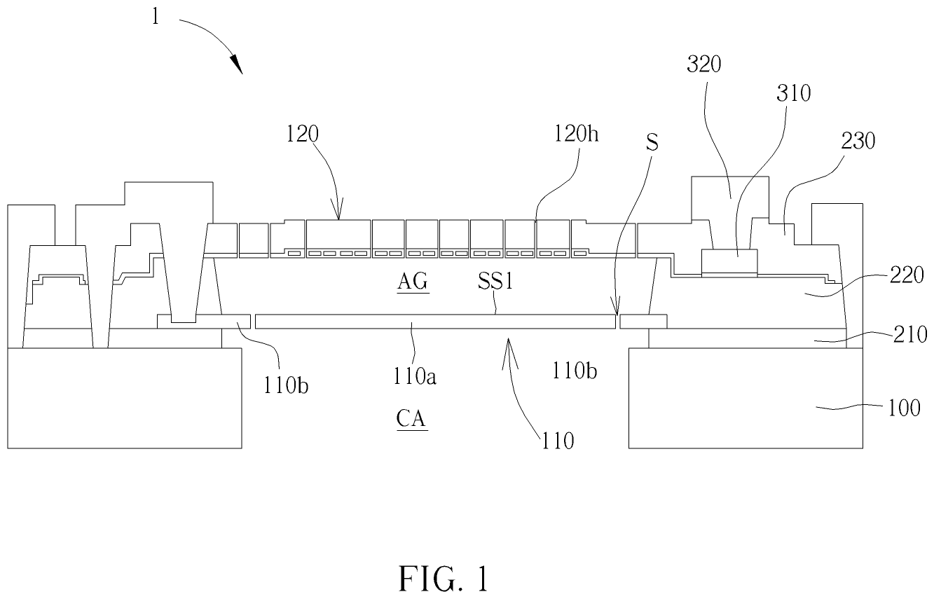

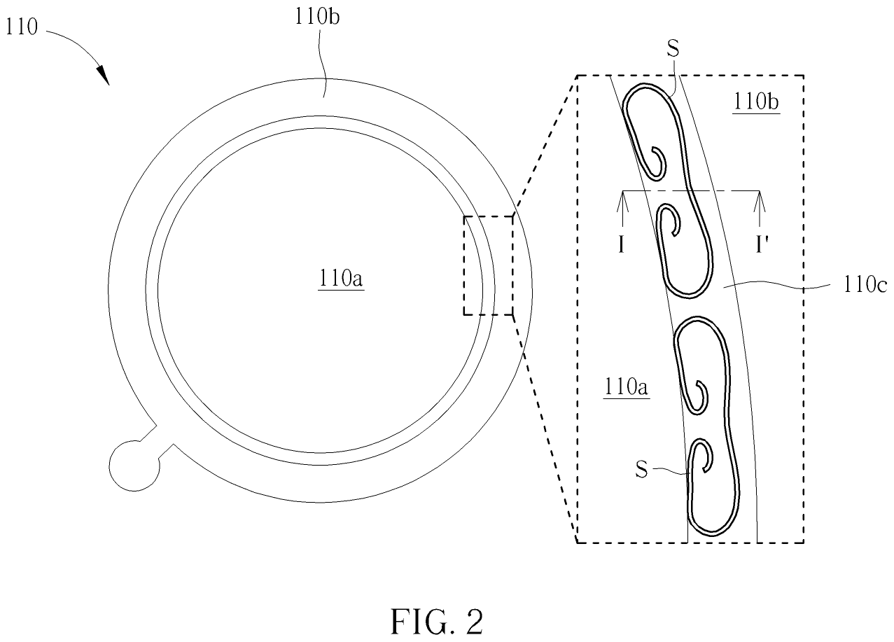

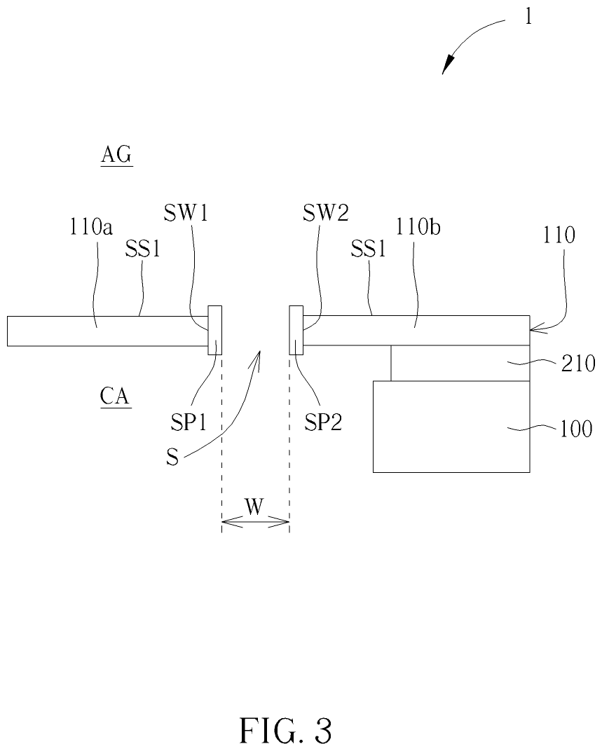

Please refer to FIG. 1 to FIG. 3. FIG. 1 is a schematic cross-sectional view of the MEMS microphone 1 according to an embodiment of the present invention. FIG. 2 is a top view and an enlarged view of the membrane of the MEMS microphone 1. FIG. 3 is a schematic cross-sectional view of the membrane of FIG. 2 taken along line I-I′.

As shown in FIG. 1 to FIG. 3, the MEMS microphone 1 includes a substrate 100 and a membrane 110 supported relative to the substrate 100. According to an embodiment of the present invention, for example, the substrate 100 may be a silicon substrate, and the membrane 110 may be a polysilicon membrane. According to an embodiment of the present invention, for example, the thickness of the membrane 110 is 8000 angstroms.

According to an embodiment of the present invention, the membrane 110 includes an inner portion 110a and an outer portion 110b. According to an embodiment of the present invention, the outer portion 110b may be annular and surround the inner portion 110a, and the outer portion 110b is only connected to the inner portion 110a through the connecting portion 110c.

According to an embodiment of the present invention, as shown in FIG. 3, a first spacer SP1 is provided on the sidewall SW1 of the inner portion 110a, directly facing the outer portion 110b, and a second spacer SP2 is provided on the sidewall SW2 of the outer portion 110b directly facing the inner portion 110a. According to an embodiment of the present invention, a slit S is formed between the first spacer SP1 and the second spacer SP2. According to an embodiment of the present invention, for example, the width W of the slit S may be about 0.1 μm, but is not limited thereto.

According to an embodiment of the present invention, as shown in FIG. 1, the MEMS microphone 1 further includes a cavity CA located in the substrate 100 and under the membrane 110. According to an embodiment of the present invention, the MEMS microphone 1 further includes a backplate 120 located above the membrane 110. According to an embodiment of the present invention, a plurality of acoustic holes 120h may be provided in the backplate 120. According to an embodiment of the present invention, the MEMS microphone 1 further includes an air gap AG located between the membrane 110 and the backplate 120. According to an embodiment of the present invention, the slit S communicates the air gap AG and the cavity CA.

According to an embodiment of the present invention, a silicon oxide layer 210 may be disposed between the outer portion 110b and the substrate 100. For example, the thickness of the silicon oxide layer 210 is about 7500 angstroms, but not limited thereto. According to an embodiment of the present invention, a silicon oxide layer 220 may be disposed on the silicon oxide layer 210. According to an embodiment of the present invention, the outer portion 110b is fixedly sandwiched between the silicon oxide layer 210 and the silicon oxide layer 220.

According to an embodiment of the present invention, a silicon nitride layer 230 may be disposed on the silicon oxide layer 220. According to an embodiment of the present invention, the metal structure 310 and the contact structure 320 may be disposed in the silicon nitride layer 230.

According to an embodiment of the present invention, as shown in FIG. 3, the membrane 110 includes a top surface SS1 facing the backplate 120. The first spacer SP1 protrudes from the top surface SS1 of the membrane 110. According to an embodiment of the present invention, the second spacer SP2 protrudes from the top surface SS1 of the membrane 110.

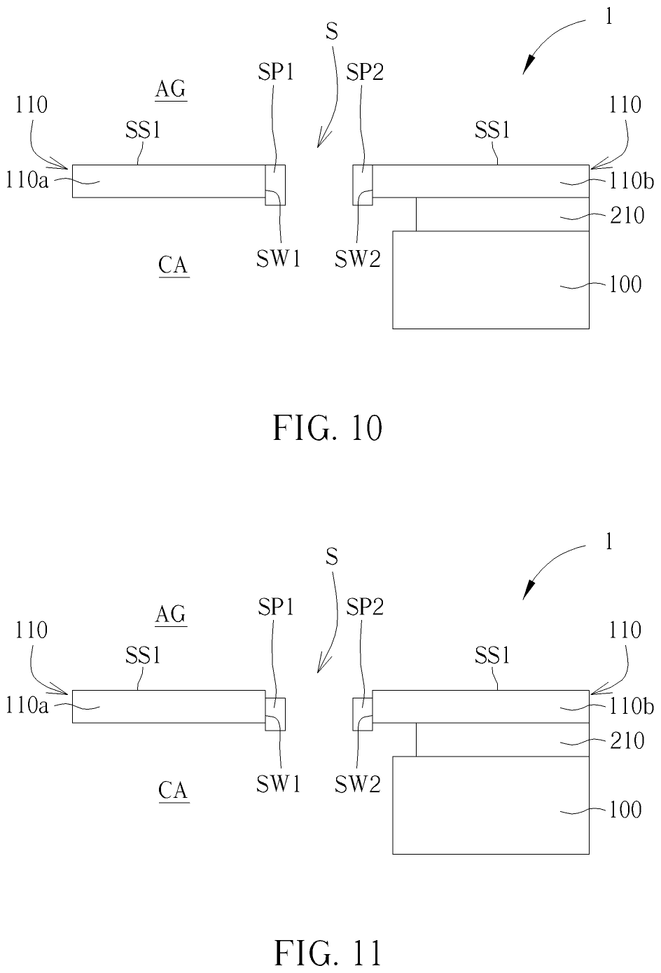

According to another embodiment of the present invention, as shown in FIG. 10, the top surfaces of the first spacer SP1 and the second spacer SP2 are approximately flush with the top surface SS1 of the membrane 110. According to yet another embodiment of the present invention, as shown in FIG. 11, the top surfaces of the first spacer SP1 and the second spacer SP2 are slightly lower than the top surface SS1 of the membrane 110.

According to an embodiment of the present invention, for example, the first spacer SP1 may include silicon nitride, silicon carbide, silicon oxycarbide, silicon, polysilicon, titanium nitride, or any combination thereof. According to an embodiment of the present invention, for example, the second spacer SP2 may include silicon nitride, silicon carbide, silicon oxycarbide, silicon, polysilicon, titanium nitride, or any combination thereof.

One advantage of the present invention is that the membrane 110 of the MEMS microphone 1 has a slit S, so it can have higher SNR and better sensitivity. In addition, the width W of the slit S can be reduced to 0.1 μm by arranging a spacer on the sidewall of the slit S, which enables the MEMS microphone 1 to have better LFRO performance at the same time.

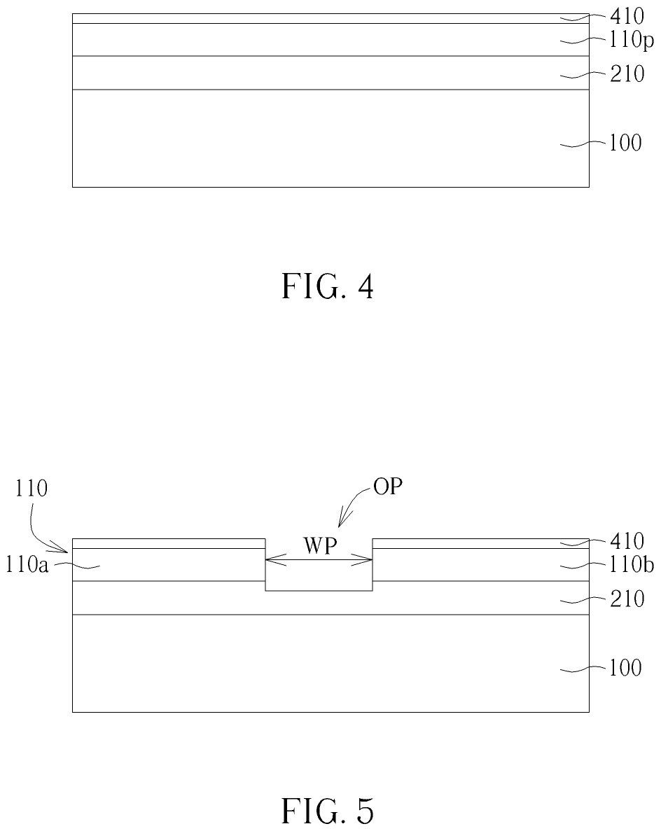

Another aspect of the present invention provides a method of fabricating a MEMS microphone. Please refer to FIG. 4 to FIG. 9, which are schematic diagrams of a method for fabricating a membrane of a MEMS microphone according to an embodiment of the present invention. As shown in FIG. 4, a substrate 100, for example, a silicon substrate is first provided. Next, a silicon oxide layer 210 with a thickness of about 7500 angstroms and a polysilicon layer 110p with a thickness of about 8000 angstroms are sequentially formed on the substrate 100. A silicon oxide layer 410 with a thickness of about 200 angstroms is then formed on the polysilicon layer 110p.

As shown in FIG. 5, a lithography process and an etching process are then performed to form an opening OP in the silicon oxide layer 410 and the polysilicon layer 110p penetrating the entire thickness of the polysilicon layer 110p. The opening OP has a width WP of about 0.5μm. At this point, the polysilicon layer 110p is patterned into a membrane 110 having an inner portion 110a and an outer portion 110b.

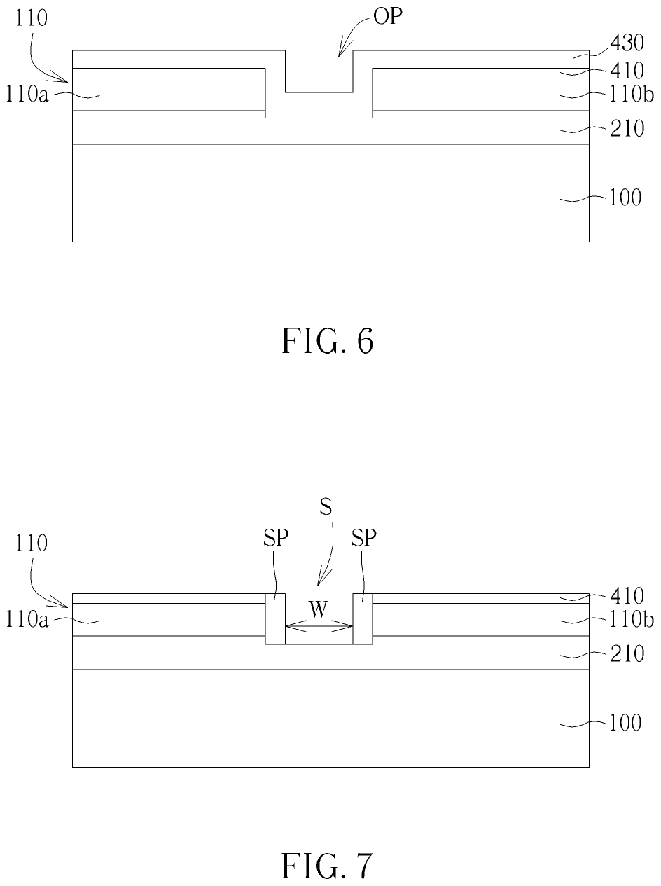

As shown in FIG. 6, next, a chemical vapor deposition (CVD) process is performed to uniformly deposit a spacer layer 430 on the silicon oxide layer 410 and in the opening OP. According to an embodiment of the present invention, for example, the thickness of the spacer layer 430 is, for example, about 2000 angstroms. According to embodiments of the present invention, for example, the spacer layer 430 may include silicon nitride, silicon carbide, silicon oxycarbide, silicon, polysilicon, titanium nitride, or any combination thereof.

As shown in FIG. 7, then, an anisotropic dry etching process is performed to etch away the spacer layer 430 on the silicon oxide layer 410, so that spacers SP are formed on the sidewalls of the opening OP. The width W of the slit S between the spacers SP is, for example, about 0.1 μm.

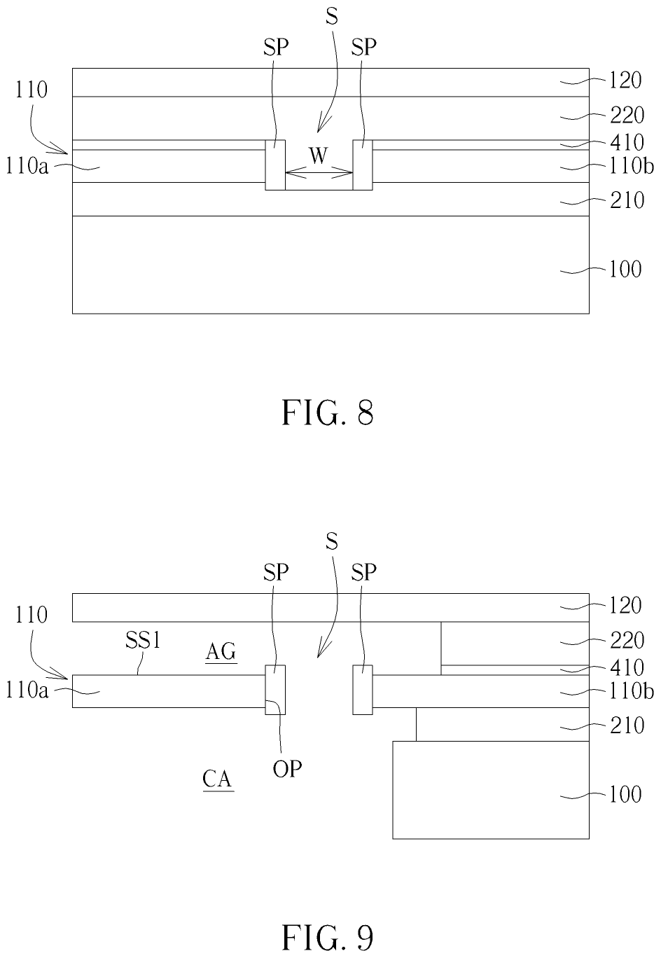

As shown in FIG. 8, next, a CVD process is performed to deposit a silicon oxide layer 220 on the silicon oxide layer 410, and the silicon oxide layer 220 is filled into the slit S. Then, the backplate 120 is formed on the silicon oxide layer 220. According to embodiments of the present invention, for example, the backplate 120 may include a silicon nitride layer, a polysilicon layer, or a combination thereof.

As shown in FIG. 9, then, an etching process is performed to remove part of the substrate 100, the silicon oxide layer 210, the silicon oxide layer 220 and the silicon oxide layer 410, and a cavity CA is formed in the substrate 100 and under the membrane 110, and an air gap AG is formed between the membrane 110 and the backplate 120. According to an embodiment of the present invention, the slit S communicates the air gap AG and the cavity CA. According to an embodiment of the present invention, the membrane 110 includes a top surface SS1 facing the backplate 120, and the spacers SP in the opening OP protrude from the top surface SS1 of the membrane 110, thereby forming the MEMS microphone 1, which includes the substrate 100, the membrane 110 supported relative to the substrate 100, the opening OP penetrating the entire thickness of the membrane 110, and the spacer SP disposed on the sidewall of the opening OP.

The method for manufacturing a MEMS microphone of the present invention includes: providing a substrate 100; forming a membrane 110 supported relative to the substrate 100; forming an opening OP penetrating the entire thickness of the membrane 110; and forming a spacer SP on the sidewall of the opening OP.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A microelectromechanical system (MEMS) microphone, comprising:
a substrate;
a membrane supported relative to the substrate, wherein the membrane comprises an inner portion and an outer portion;
a first spacer disposed on a sidewall of the inner portion directly facing the outer portion;
a second spacer disposed on a sidewall of the outer portion directly facing the inner portion; and
a slit between the first spacer and the second spacer.

2. The MEMS microphone according to claim 1, wherein the substrate is a silicon substrate and the membrane is a polysilicon membrane.

3. The MEMS microphone according to claim 1 further comprising:
a cavity in the substrate and under the membrane;
a backplate above the membrane, wherein the membrane comprises a top surface facing the backplate; and
an air gap between the membrane and the backplate.

4. The MEMS microphone according to claim 3, wherein the slit communicates the air gap with the cavity.

5. The MEMS microphone according to claim 3, wherein the first spacer and the second spacer protrude from the top surface of the membrane.

6. The MEMS microphone according to claim 3, wherein a top surface of the first spacer and the second spacer is flush with the top surface of the membrane.

7. The MEMS microphone according to claim 3, wherein a top surface of the first spacer and the second spacer is lower than the top surface of the membrane.

8. The MEMS microphone according to claim 1, wherein the first spacer comprises silicon nitride, silicon carbide, silicon oxycarbide, silicon, polysilicon, titanium nitride, or any combinations thereof.

9. The MEMS microphone according to claim 1, wherein the second spacer comprises silicon nitride, silicon carbide, silicon oxycarbide, silicon, polysilicon, titanium nitride, or any combinations thereof.

10. The MEMS microphone according to claim 1 further comprising:
a silicon oxide layer between the outer portion and the substrate.

11. A method of fabricating a microelectromechanical system (MEMS) microphone, comprising:
providing a substrate;
forming a membrane supported relative to the substrate, wherein the membrane comprises an inner portion and an outer portion;
forming a first spacer on a sidewall of the inner portion directly facing the outer portion;
forming a second spacer on a sidewall of the outer portion directly facing the inner portion; and
forming a slit between the first spacer and the second spacer.

12. The method according to claim 11, wherein the substrate is a silicon substrate and the membrane is a polysilicon membrane.

13. The method according to claim 11 further comprising:
forming a cavity in the substrate and under the membrane;
forming a backplate above the membrane; and
forming an air gap between the membrane and the backplate.

14. The method according to claim 13, wherein the slit communicates the air gap with the cavity.

15. The method according to claim 11, wherein the first spacer comprises silicon nitride, silicon carbide, silicon oxycarbide, silicon, polysilicon, titanium nitride, or any combinations thereof.

16. The method according to claim 11, wherein the second spacer comprises silicon nitride, silicon carbide, silicon oxycarbide, silicon, polysilicon, titanium nitride, or any combinations thereof.

17. The method according to claim 11 further comprising:
forming a silicon oxide layer between the outer portion and the substrate.

18. A microelectromechanical system (MEMS) microphone, comprising:
a substrate;
a membrane supported relative to the substrate;
an opening penetrating through an entire thickness of the membrane; and
a spacer disposed on a sidewall of the opening.

19. A method of fabricating a microelectromechanical system (MEMS) microphone, comprising:
providing a substrate;
forming a membrane supported relative to the substrate;
forming an opening penetrating through an entire thickness of the membrane; and
forming a spacer disposed on a sidewall of the opening.
